(19) United States
(12) Patent Application Publication
(10) Pub. No.: US 2021/0162907 A1
(43) Pub. Date: Jun. 3, 2021

(54) FLOOR CARPET WITH ELECTROMAGNETIC SHIELDING AND IMPROVED ACOUSTIC DAMPENING

(71) Applicant: GM Global Technology Operations LLC, Detroit, MI (US)

(72) Inventors: Alejandro Hernandez Covarrubias, Metepec (MX); Miguel Angel Serrano Lopez, Metepec (MX)

(21) Appl. No.: 16/702,105

(22) Filed: Dec. 3, 2019

(51) Int. Cl. B60N 3/04; H05K 9/00; B60R 13/08

(52) U.S. Cl. CPC B60N 3/048; H05K 9/009; B29L 2031/3017; B60N 3/042; B60R 13/0815

(57) ABSTRACT

A floor carpet for an automobile comprising including a first layer of polyester carpet pile, a dissipative layer, wherein the dissipative layer is a compressed matrix of electrically conductive metal wool and acoustic dampening fibers, the acoustic dampening fibers being one of cotton fibers and synthetic fibers, and a third layer including a sound dampening backing that is one of wool and polyurethane, wherein, the first layer, dissipative layer, and third layer are molded together as a unitary piece that is shaped to conform to the contour of a floor panel within an automobile and adapted to be immovably installed within the automobile.

### INTRODUCTION

The present disclosure relates to a floor carpet for the interior of an automobile that includes electromagnetic shielding and improved acoustic dampening incorporated therein.

More and more, vehicles are being developed with hybrid and full electrical powertrains. These vehicles require the use of high voltage batteries and electrical cables to store and transfer electricity for the electrical components within the vehicle. While generally, such batteries and cables are positioned outside the passenger compartment of the vehicle, electromagnetic radiation can pass into the vehicle. In many instances, batteries and cables are mounted below the floor of the vehicle. To protect the passengers and sensitive electronics within the vehicle from exposure to electromagnetic emissions, it is desirable to control the amount of electromagnetic emissions that pass through the floor of the vehicle into the passenger compartment.

Thus, there is a need for a floor carpet for an automobile that includes an electromagnetic shield incorporated therein.

### SUMMARY

According to several aspects of the present disclosure a floor carpet for an automobile includes a first layer of carpet pile, a dissipative layer including an electromagnetic shield and acoustic dampening, and a third layer including a sound dampening backing, wherein, the first layer, the dissipative layer, and third layer are molded together as a unitary piece.

According to another aspect, the carpet pile is polyester.

According to another aspect, the sound dampening backing is wool.

According to another aspect, the sound dampening backing is polyurethane.

According to another aspect, the dissipative layer includes a first material adapted to provide electromagnetic shielding, and a second material adapted to provide acoustic dampening, wherein the dissipative layer includes a compressed matrix of the first and second materials.

According to another aspect, the first material is metal wool.

According to another aspect, the metal wool is made from an electrically conductive metal.

According to another aspect, the second material is cotton fiber.

According to another aspect, the second material is synthetic fiber.

According to another aspect, the amount of electromagnetic shielding provided by the floor carpet can be tuned by varying the density of the first material present in the dissipative layer.

According to another aspect, the floor carpet is shaped to conform to the contour of a floor panel within an automobile and to be immovably installed within the automobile.

According to another aspect, the dissipative layer extends across substantially all of the floor carpet to provide electromagnetic shielding and acoustic dampening across substantially the entire floor of the automobile.

According to another aspect, the dissipative layer is located at a position within the floor carpet to provide localized electromagnetic shielding and acoustic dampening at a specific location.

According to another aspect, the floor carpet is portable and can be moved within an automobile or selectively used in different automobiles.

According to several aspects of the present disclosure, a floor carpet for an automobile includes a first layer of polyester carpet pile, a dissipative layer, wherein the dissipative layer is a compressed matrix of electrically conductive metal wool and acoustic dampening fibers, the acoustic dampening fibers being one of cotton fibers and synthetic fibers, and a third layer including a sound dampening backing that is one of wool and polyurethane, wherein, the first layer, the dissipative layer, and third layer are molded together as a unitary piece that is shaped to conform to the contour of a floor panel within an automobile and adapted to be immovably installed within the automobile.

According to another aspect, the dissipative layer extends across substantially all of the floor carpet to provide electromagnetic shielding across substantially the entire floor of the automobile.

According to another aspect, the dissipative layer is located at a position within the floor carpet to provide localized electromagnetic shielding and acoustic dampening at a specific location.

According to several aspects of the present disclosure, a method of forming a floor carpet having an electromagnetic shield and acoustic dampening includes forming a dissipative layer by compressing a matrix of electrically conductive metal wool and acoustic dampening fibers, the acoustic dampening fibers being one of cotton fibers and synthetic fibers, placing the dissipative layer between a layer of pile carpet and a backing material, and thermo-molding the pile carpet, the dissipative layer, and the backing material together in a shape that conforms to the contour of a floor panel within an automobile.

According to another aspect, a method of forming a floor carpet having an electromagnetic shield and acoustic dampening further includes forming a layer of carpet pile in a first mold, removing the layer of carpet pile from the first mold and placing the layer of carpet pile within a second mold, placing the dissipative layer within the second mold, and injection molding a polyurethane backing material into the second mold to create a mechanical bond between the carpet pile and the polyurethane backing material, encapsulating the dissipative layer therebetween.

According to another aspect, a method of forming a floor carpet having an electromagnetic shield and acoustic dampening includes varying the density of the electrically conductive metal wool within the dissipative layer to vary the amount of electromagnetic shielding provided by the dissipative layer.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a side sectional view of a floor carpet according to an exemplary embodiment;

FIG. 2 is a close up view of a dissipative layer according to an exemplary embodiment;

FIG. 3 is a schematic view of a method of forming a floor carpet according to an exemplary embodiment; and

FIG. 4 is a schematic view of a method of forming a floor carpet according to another exemplary embodiment.

### DETAILED DESCRIPTION

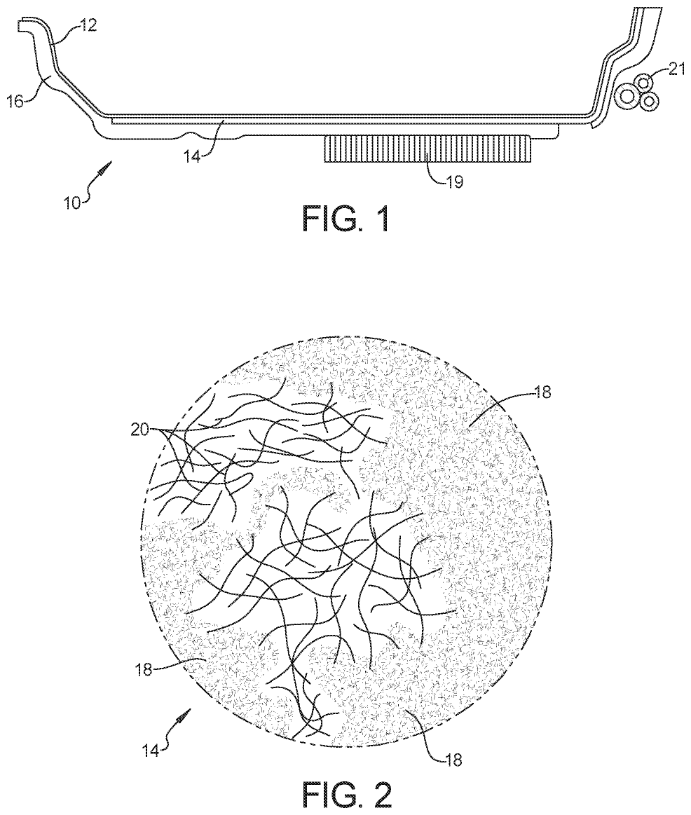

The following description is merely exemplary in nature and is not intended to limit the present disclosure, application, or uses. Referring to FIG. 1, a floor carpet 10 for an automobile in accordance with the present disclosure includes a first layer 12 of carpet pile, a dissipative layer 14 that includes electromagnetic shielding and acoustic dampening, and a third layer 16 of sound dampening backing. The first layer 12, the dissipative layer 14, and third layer 16 are molded together as a unitary piece to provide a floor carpet 10 for the automobile that includes an electromagnetic shield and acoustic dampening incorporated therein.

The first layer 12 may be any known floor carpeting adapted for an automobile, such as polyester. The third layer 16 may be made from any material suited for use within an automobile. In one exemplary embodiment, the third layer 16 of the floor carpet 10 is made from wool. Wool will provide good heat insulation and sound dampening qualities that are desired in automobile floor carpeting. In another exemplary embodiment, the third layer 16 of the floor carpet 10 is made from polyurethane. Polyurethane also provides good sound dampening qualities and is suited to molding techniques used to form the floor carpeting 10.

Referring to FIG. 2, the dissipative layer 14 includes a first material 18 and a second material 20. The first material 18 is adapted to provide electromagnetic shielding. The second material 20 is adapted to provide acoustic dampening. The dissipative layer 14 comprises a compressed matrix of the first and second materials 18, 20. The first material 18 will absorb electromagnetic emissions from outside the passenger vehicle, blocking at least a portion of the electromagnetic emissions from entering the passenger compartment of the vehicle. Such emissions may come from batteries 19 or electric cables 21.

The amount of electromagnetic emissions that are allowed to pass through the floor carpet 10 is dependent upon the density of the first material 18 within the dissipative layer 14. In an exemplary embodiment, the first material 18 is metal wool that is made from an electrically conductive metal. The second material 20 is made from cotton or synthetic fibers that provide good acoustic insulation properties. The dissipative layer 14 is a compressed matrix of the first material 18 and the second material 20. The dissipative layer 14 can be tuned to block more or less of the electromagnetic emissions by varying the density of the first material 18 within the matrix of the dissipative layer 14, depending on the type and frequency of electromagnetic emissions.

In one exemplary embodiment, the floor carpet 10 is shaped to conform to the contour of a floor panel within an automobile. The floor carpet 10 is installed within the automobile and fits exactly to the contour and size of the floor panel within the automobile. The floor carpet 10 is secured to the floor panel of the automobile. In one exemplary embodiment, the dissipative layer 14 extends across substantially all of the floor carpet 10 to provide electromagnetic shielding and added acoustic dampening across substantially the entire floor of the automobile. Alternatively, in another exemplary embodiment, the dissipative layer 14 is located at a position within the floor carpet to provide localized electromagnetic shielding at a specific location of the floor panel within the automobile.

In another exemplary embodiment, the floor carpet 10 is portable and can be moved within an automobile or selectively used in different automobiles. In this instance, rather than having a shape that contours to the shape and size of the automobile, the floor carpet has a generic round, square, or rectangular shape, or a custom shape to fit within contour features of the floor panel of the automobile, such as a floor mat. This type of floor carpet 10 can be moved within the automobile, or removed from the automobile entirely.

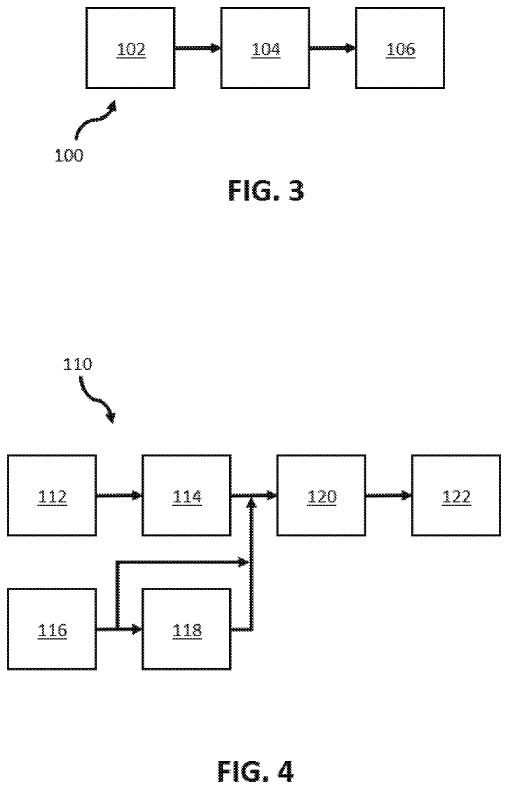

Referring to FIG. 3, a method of forming a floor carpet 10 having an electromagnetic shield and acoustic dampening is shown generally at 100. Starting at block 102, the method includes forming a dissipative layer 14 by compressing a matrix of electrically conductive metal wool and acoustic dampening fibers, wherein the acoustic dampening fibers are cotton or synthetic fibers. Moving to block 104, the method includes placing the dissipative layer 14 between a layer of pile carpet (first layer) 12 and a backing material (third layer) 16. Moving to block 106, the method includes thermo-molding the pile carpet 12 and backing material 16 together, with the dissipative layer 14 therebetween. In an exemplary embodiment, the carpet pile 12, the dissipative layer 14 and the backing material 16 are thermo-molded together in a shape that conforms to the contour of a floor panel within an automobile.

Referring to FIG. 4, a method according to an exemplary embodiment is shown at 110. Starting at block 112, the method includes forming the carpet pile 12 separately in a first mold. Moving to block 114, the carpet pile 12 is removed from the first mold and placed within a second mold. The second mold will provide the final shape for the floor carpet 10.

At block 116, the dissipative layer 14 is formed by compressing a matrix of electrically conductive metal wool and acoustic dampening fibers, wherein the acoustic dampening fibers are cotton or synthetic fibers. At block 118, the method includes varying the density of the electrically conductive metal wool within the dissipative layer 14 vary the amount of electromagnetic shielding provided by the dissipative layer 14. This step allows the floor carpet 10 to be tuned for a specific application depending on the type and frequency of electromagnetic emissions that the floor carpet 10 is expected to experience.

At block 120, the method includes placing the dissipative layer 14 within the second mold, in engagement with the carpet pile 12. If the dissipative layer 14 is meant to cover the entire expanse of the floor carpet 10, the dissipative layer 14 is aligned with the carpet pile 12 accordingly. If the floor carpet 10 is being designed to provide electromagnetic shielding only within a specified location, the dissipative layer 14 is placed within the second mold, in engagement with the carpet pile 12 at the location where electromagnetic shielding is desired.

Moving to block 122, the method includes injection molding a polyurethane backing material 16 into the second mold. The polyurethane material fills the second mold and creates a mechanical bond between the carpet pile 12 and the polyurethane backing material 16. The dissipative layer 14 is encapsulated between the carpet pile 12 and the polyurethane backing material 16.

In an exemplary embodiment, the second mold is shaped and sized for a specific application and the method includes molding the pile carpet 12 and backing material 16 together, with the electromagnetic shield 14 therebetween in a shape that conforms the contour of a floor panel within an automobile. The finished floor carpet 10 will be semi-rigid and will match the inner contour of the floor panel of the automobile allowing the floor carpet 10 to be easily installed within the automobile during assembly.

A floor carpet 10 of the present disclosure offers several advantages. These include providing a floor carpet 10 that includes dissipative layer 14 incorporated therein that provides electromagnetic shielding and added acoustic dampening. This reduces assembly time and complexity, and reduces the number of components during assembly of an automobile. Further, the floor carpet 10 of the present disclosure allows the electromagnetic shielding properties of the dissipative layer 14 to be tuned for specific applications depending on the type of and frequency of electromagnetic emissions. Finally, the floor carpet 10 of the present disclosure can be designed to provide electromagnetic shielding of the entire floor of the automobile, or alternatively, maybe designed to provide localized electromagnetic shielding at specific locations within the automobile.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A floor carpet for an automobile, comprising:
a first layer of carpet pile;
a dissipative layer including an electromagnetic shield and acoustic dampening; and
a third layer including a sound dampening backing;
wherein, the first layer, the dissipative layer, and third layer are molded together as a unitary piece.

2. The floor carpet of claim 1, wherein the carpet pile is polyester.

3. The floor carpet of claim 1, wherein the backing is wool.

4. The floor carpet of claim 1, wherein the backing is polyurethane.

5. The floor carpet of claim 1, wherein the dissipative layer includes:
a first material adapted to provide electromagnetic shielding;
a second material adapted to provide acoustic dampening;
wherein, the dissipative layer includes a compressed matrix of the first and second materials.

6. The floor carpet of claim 5, wherein the first material is metal wool.

7. The floor carpet of claim 6, wherein the metal wool is made from an electrically conductive metal.

8. The floor carpet of claim 6, wherein the second material is cotton fiber.

9. The floor carpet of claim 6, wherein the second material is synthetic fiber.

10. The floor carpet of claim 6, wherein the amount of electromagnetic shielding provided by the floor carpet can be tuned by varying the density of the first material present in the dissipative layer.

11. The floor carper of claim 1, wherein the floor carpet is shaped to conform to the contour of a floor panel within an automobile and to be immovably installed within the automobile.

12. The floor carpet of claim 11, wherein the dissipative layer extends across substantially all of the floor carpet to provide electromagnetic shielding and acoustic dampening across substantially the entire floor of the automobile.

13. The floor carpet of claim 11, wherein the dissipative layer is located at a position within the floor carpet to provide localized electromagnetic shielding and acoustic dampening at a specific location.

14. The floor carpet of claim 1, wherein the floor carpet is portable and can be moved within an automobile or selectively used in different automobiles.

15. A floor carpet for an automobile, comprising:
a first layer of polyester carpet pile;
a dissipative layer, wherein the dissipative layer is a compressed matrix of electrically conductive metal wool and acoustic dampening fibers, the acoustic dampening fibers being one of cotton fibers and synthetic fibers; and
a third layer including a sound dampening backing that is one of wool and polyurethane;
wherein, the first layer, the dissipative layer, and third layer are molded together as a unitary piece that is shaped to conform to the contour of a floor panel within an automobile and adapted to be immovably installed within the automobile.

16. The floor carpet of claim 15, wherein the dissipative layer extends across substantially all of the floor carpet to provide electromagnetic shielding across substantially the entire floor of the automobile.

17. The floor carpet of claim 15, wherein the dissipative layer is located at a position within the floor carpet to provide localized electromagnetic shielding and acoustic dampening at a specific location.

18. A method of forming a floor carpet having an electromagnetic shield and acoustic dampening comprising:
forming a dissipative layer by compressing a matrix of electrically conductive metal wool and acoustic dampening fibers, the acoustic dampening fibers being one of cotton fibers and synthetic fibers;
placing the dissipative layer between a layer of pile carpet and a backing material; and
thermo-molding the pile carpet, the dissipative layer, and the backing material together in a shape that conforms to the contour of a floor panel within an automobile.

19. The method of claim 18, further including:
forming a layer of carpet pile in a first mold;
removing the layer of carpet pile from the first mold and placing the layer of carpet pile within a second mold;
placing the dissipative layer within the second mold; and
injection molding a polyurethane backing material into the second mold to create a mechanical bond between the carpet pile and the polyurethane backing material, encapsulating the dissipative layer therebetween.

20. The method of claim 19, including varying the density of the electrically conductive metal wool within the dissipative layer to vary the amount of electromagnetic shielding provided by the dissipative layer.
